(19) United States
(12) Patent Application Publication
(10) Pub. No.: US 2010/0138176 A1
(43) Pub. Date: Jun. 3, 2010

(54) System for accurate battery run time estimation utilizing voltage capture and coulomb counting

(75) Inventor: Huili Yu, Mission Viejp, CA (US)

Correspondence Address: FARJAMI & FARJAMI LLP, 26522 LA ALAMEDA AVENUE, SUITE 360, MISSION VIEJO, CA, 92691, US

(73) Assignee: BROADCOM CORPORATION, Irvine, CA (US)

(21) Appl. No.: 12/315,428

(22) Filed: Dec. 2, 2008

(51) Int. Cl. G01R 31/36

(52) U.S. Cl. 702/63

(57) ABSTRACT

A disclosed embodiment is a low-cost, low-power system for run time estimation of a battery utilized by an electronic device. The system comprises a voltage capture circuit configured to measure a voltage of the battery and a coulomb counting circuit configured to measure a charge of the battery. Additionally, the voltage capture circuit is configured to measure an open-circuit voltage of the battery during a sleep mode, or battery voltage during an operation mode, and the coulomb counting circuit is configured to measure a discharge of the battery during the sleep mode, or a change or discharge of battery during an operation mode. The voltage capture circuit comprises a sample-and-hold circuit and an analog-to-digital converter, while the coulomb counting circuit comprises a sigma-delta converter, a comb filter, and a digital accumulator. The voltage capture circuit and the coulomb counting circuit are coupled through a power management unit to a microprocessor configured to estimate battery run time in the electronic device.

### BACKGROUND OF THE INVENTION

1. Field of the Invention

The present invention is generally in the field of electronic devices. More particularly, the invention is in the field of battery and power management for electronic devices.

2. Background Art

Many modern electronic devices that are powered by a battery implement some method of monitoring the battery to estimate battery run time. For example, cellular telephones, portable music players, digital cameras, and other devices each typically include a system for monitoring the battery coupled to the device. Presently, two types of systems are typically used. The first type of system measures the battery voltage, and provides that battery voltage to the device for use in estimating the battery run time. The second type of system tracks the charge applied to and taken from the battery, and provides that information to the device for use in estimating the battery run time. Both types of conventional systems have attendant drawbacks.

For example, the first type of system, which monitors battery voltage, can provide only rough battery run time estimates because the relationship between battery voltage and battery capacity varies according to the load placed on the battery by the device. Typically, the load placed on the battery varies dynamically depending on what function the device is performing, thus making battery capacity and run time estimation difficult. The second type of system, which tracks the charge applied to and taken from the battery, can in some cases be utilized to provide more accurate battery run time estimates than the first type of system. However, implementing the second type of system tends to be expensive, and such systems are typically implemented in the battery of a device, instead of in the device itself, because otherwise tracked charge will become inaccurate when batteries are replaced. This type of system can also suffer inaccuracies when tracked batteries are not deeply discharged and then fully charged.

Thus, there is a need in the art for a system for accurate battery run time estimation that overcomes the disadvantages associated with utilizing conventional systems.

### SUMMARY OF THE INVENTION

A system for accurate battery run time estimation utilizing voltage capture and coulomb counting, substantially as shown in and/or described in connection with at least one of the figures, and as set forth more completely in the claims.

### BRIEF DESCRIPTION OF THE DRAWINGS

FIG. 1 shows an exemplary system according to one embodiment of the present invention.

FIG. 2 illustrates a portion of the exemplary system of FIG. 1 according to one embodiment of the present invention.

FIG. 3 illustrates a portion of the exemplary system of FIG. 1 according to one embodiment of the present invention.

### DETAILED DESCRIPTION OF THE INVENTION

The present invention is directed to a system for accurate battery run time estimation utilizing voltage capture and coulomb counting. Although the invention is described with respect to specific embodiments, the principles of the invention, as defined by the claims appended herein, can obviously be applied beyond the specific embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

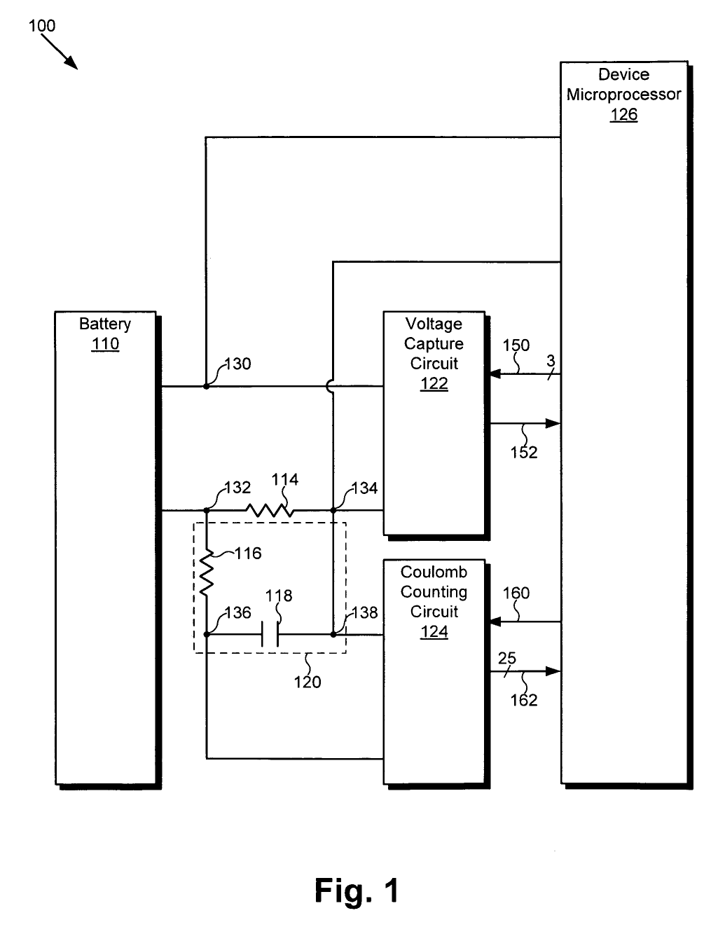

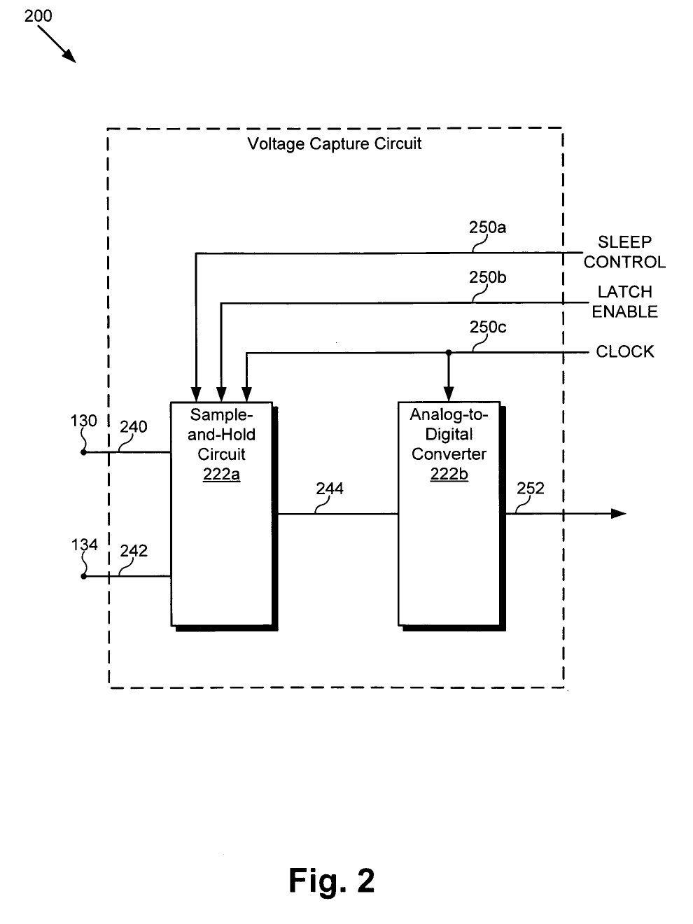

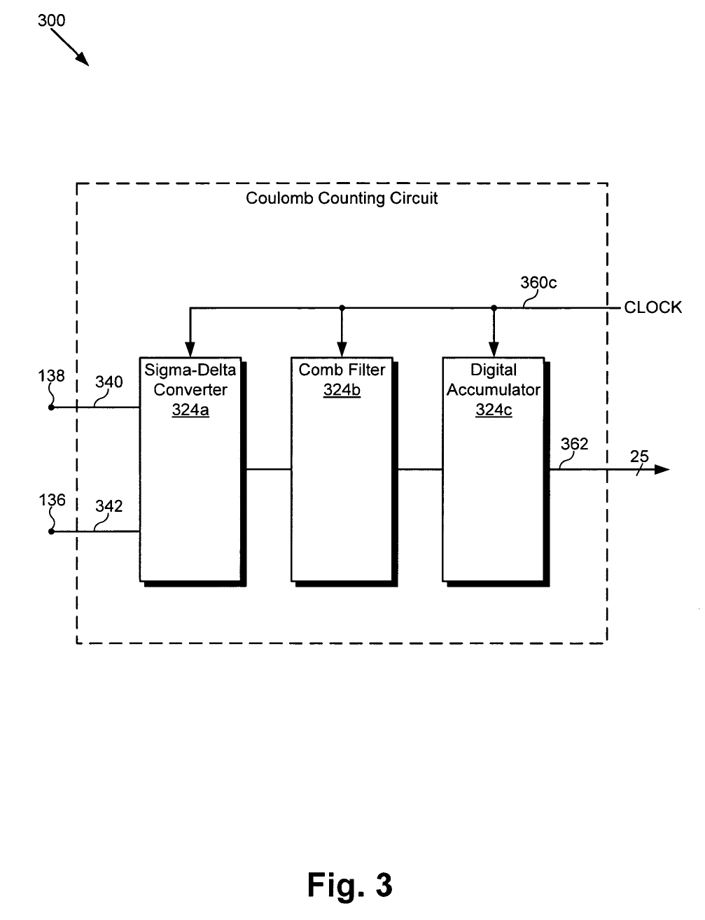

FIG. 1 shows system 100 according to one embodiment of the present invention. System 100 is configured, for example, for low-cost, low-power battery run time estimation. As shown in FIG. 1, system 100 includes battery 110, voltage capture circuit 122, coulomb counting circuit 124, and device microprocessor 126 in one embodiment. System 100 also includes, in one embodiment, current sensing resistor 114 (referred to generally as a “current sensor” in the present application), low-pass filter resistor 116, and low-pass filter capacitor 118. Together, in one embodiment low-pass filter resistor 116 and low-pass filter capacitor 118 comprise low-pass filter 120. A configuration of voltage capture circuit 122 according to one embodiment of the invention is described in more detail in FIG. 2, while a configuration of coulomb counting circuit 124 according to one embodiment of the invention is described in more detail in FIG. 3.

Battery 110 comprises, in one embodiment, a lithium-ion battery. In another embodiment, battery 110 comprises a plurality of lithium-ion batteries coupled, for example, in series or parallel, as known in the art. In yet another embodiment, battery 110 is implemented as a type of battery other than a lithium-ion battery. Battery 110 comprises, in one embodiment, battery terminals as known in the art coupled to node 130 and node 132. In one embodiment, battery 110 is coupled via node 130 and node 132 to device microprocessor 126, voltage capture circuit 122, and coulomb counting circuit 124.

Battery 110 is coupled, in one embodiment, to device microprocessor 126 via node 130 and across current-sensing resistor 114 via node 132 and node 134. So coupled, in one embodiment battery 110 provides energy to device microprocessor 126 while discharging, and also receives energy from device microprocessor 126 through power manage unit while charging. To facilitate discharging and charging battery 10, in one embodiment device microprocessor 126 comprises a power management unit (PMU) as known in the art. Additionally, in one embodiment, device microprocessor 126 is configured to operate in a sleep mode in which device microprocessor 126 operates using reduced power.

Battery 110 is also coupled, in one embodiment, to voltage capture circuit 122 via node 130 and across current-sensing resistor 114 via node 132 and node 134. So coupled, voltage capture circuit 122 is configured, in one embodiment, to measure the voltage between node 130 and node 134. The voltage between node 130 and node 134 varies, for example, with the charge or discharge on battery 110 and with the load placed on battery 110 by device microprocessor 126. The voltage measured by voltage capture circuit 122 is also utilized, in one embodiment, by system 100 in estimating the run time of battery 110. Voltage capture circuit 122 provides a voltage capture circuit output to device microprocessor 126 via bus 152.

In one embodiment, battery 110 is coupled across low-pass filter 120 to coulomb counting circuit 124. Specifically, in one embodiment both ends of current sensing resistor 114 at node 132 and node 134 are coupled to low-pass filter 120, and coulomb counting circuit 124 is coupled to low-pass filter 120 at node 136 and node 138. In one embodiment, current-sensing resistor 114 develops a current signal (e.g., a voltage drop) proportional to the current flowing between battery 110 and device microprocessor 126 while either discharging or charging. Thus, in one embodiment, the current signal of current-sensing resistor 114 is received by coulomb counting circuit 124 after filtering by low-pass filter 120. The values of low-pass filter resistor 116 and low-pass filter capacitor 118 are selected, in one embodiment, to produce a cutoff frequency of low-pass filter 120 of approximately 0.5 hertz. By thus limiting the maximum frequency of the current signal received by coulomb counting circuit 124, power-saving and cost-reducing features, for example, can be implemented in coulomb counting circuit 124. In one embodiment, coulomb counting circuit 124 provides a coulomb counting circuit output to device microprocessor 126 via bus 162.

FIG. 2 shows voltage capture circuit 200 that includes, in one embodiment, sample-and-hold circuit 222a and analog-to-digital converter 222b. Together, in one embodiment sample-and-hold circuit 222a and analog-to-digital converter 222b correspond to voltage capture circuit 122 in FIG. 1. In one embodiment, line 240 in FIG. 2 is coupled to node 130 in FIG. 1, and line 242 in FIG. 2 is coupled to node 134 in FIG. 1. Also, in one embodiment, line 250a, line 250b, and line 250c in FIG. 2 are included in bus 150 in FIG. 1, while bus 252 in FIG. 2 corresponds to bus 152 in FIG. 1.

Sample-and-hold circuit 222a is configured, in one embodiment of the present invention, to sample a voltage between line 240 and line 242 and hold the sampled voltage on line 244, even if the voltage between line 240 and line 242 subsequently changes (e.g., sample-and-hold circuit 222a is implemented as a sample-and-hold as known in the art). The sampled voltage held on line 244 is received by analog-to-digital converter 222b, in one embodiment, and converted to a digital value that is output as a voltage capture circuit output to device microprocessor 126 on bus 252. In one embodiment, line 250a, line 250b and line 250c carry control signals from device microprocessor 126 to sample-and-hold circuit 222a and to analog-to-digital converter 222b.

In particular, in one embodiment line 250c carries a clock signal to both sample-and-hold circuit 222a and analog-to-digital converter 222b. The clock signal of line 250c is generated, for example, by a clock signal source in device microprocessor 126, and has, in one embodiment, a slow speed (e.g., approximately 32 kilohertz) selected for reduced power consumption during a sleep mode. Line 250b carries, in one embodiment, a latch enable signal to sample-and-hold circuit 222a, and line 250a carries a sleep control signal to sample-and-hold circuit 222a. In one embodiment, the latch enable signal of line 250b controls whether or not sample-and-hold circuit 222a will sample a voltage between line 240 and line 242 on a rising edge of the sleep control signal of line 250a. Device microprocessor 126 can thus, for example, enable or disable voltage sampling during a transition out of a sleep mode. Device microprocessor 126 can also thus, for example, operate voltage capture circuit 200 to measure an open-circuit voltage of battery 110 during a sleep mode and to store the open-circuit voltage for utilization after the sleep mode. Measuring an open-circuit voltage during a sleep mode is advantageous because, for example, during the sleep mode no dynamically varying load is placed on battery 110 to cause differing discharge voltage curves that make battery run time estimation difficult.

FIG. 3 shows coulomb counting circuit 300 that includes, in one embodiment, sigma-delta converter 324a, comb filter 324b, and digital accumulator 324c. Together, sigma-delta converter 324a, comb filter 324b, and digital accumulator 324c correspond to coulomb counting circuit 124 in FIG. 1. In one embodiment, line 340 and line 342 in FIG. 3 are coupled to low-pass filter 120 in FIG. 1 (e.g., line 340 is coupled to node 138 and line 342 is coupled to node 136). Also, in one embodiment, line 360c in FIG. 3 corresponds to line 160 in FIG. 1, while bus 362 in FIG. 3 corresponds to bus 162 in FIG. 1.

Sigma-delta converter 324a is configured, in one embodiment, to receive the current signal of current-sensing resistor 114, filtered by low-pass filter 120, on line 340 and line 342. Sigma-delta converter 324a is also configured, in one embodiment, to receive a clock signal having a slow speed (e.g., approximately 32 kilohertz) selected for reduced power consumption during a sleep mode. Notably, the clock signal carried on line 360c is, in one embodiment, generated by a clock signal source in device microprocessor 126 corresponding to the clock signal source that generates the clock signal carried on line 250c in FIG. 2. Sigma-delta converter 324a is further configured, in one embodiment, as a low-cost, first-order (e.g., one-stage) sigma-delta converter with a high (e.g. 16384) oversampling ratio to subsequently yield, for example, a 19-bit resolution of comb filter 324b. In another embodiment, sigma-delta converter 324a is implemented as another type of analog-to-digital converter. Sigma-delta converter 324a achieves a high oversampling ratio by, in one embodiment, operating at one-half the frequency of the clock signal on line 360c. In one embodiment, the high oversampling ratio is also achievable, in part, because low-pass filter 120 reduces the dynamic frequency range of the current signal (e.g., by limiting the maximum frequency of the current signal to approximately 0.5 hertz).

Comb filter 324b is configured, in one embodiment, to receive the output of sigma-delta converter 324a. Comb filter 324b is also configured, in one embodiment, as a 16384-tap comb filter designed to sum 16384 1-bit samples (i.e. the output bits of sigma-delta converter 324a) to determine moving average. Thus implemented, comb filter 324b is, for example, a simple and low-cost comb filter that does not require a complex multiplier circuit. Although 16384-tap comb filter 324b has a theoretical resolution of 19 bits, comb filter 324b is implemented, in one embodiment, to provide a signed 12-bit digital output.

Digital accumulator 324c is configured, in one embodiment, to receive the output of comb filter 324b. Digital accumulator 324c is also configured, in one embodiment, as a digital accumulator capable of storing a value having, for example, a 25-bit size. Thus, digital accumulator 324c can accumulate a plurality of 12-bit digital outputs of comb filter 324b. Digital accumulator 324c outputs an accumulated, stored value to device microprocessor 126 on bus 362. Thus, in one embodiment, coulomb counting circuit 300 can operate utilizing sigma-delta converter 324a, comb filter 324b, and digital accumulator 324c to measure a discharge of battery 110 during a sleep mode or an operation mode.

The invention's unique combination of, for example, a voltage capture circuit and a coulomb counting circuit, which together include in one embodiment a sample-and-hold circuit, an analog-to-digital converter, a sigma-delta converter, a comb filter, and a digital accumulator, as described above, permits the invention to operate with several advantages over conventional systems. For example, one embodiment of the invention avoids problems caused by estimating battery run time while a varying load is placed on the battery depending on what function the device is performing. Furthermore, for example, one embodiment of the invention utilizes a slow clock during a sleep mode to achieve low-power operation. Additionally, for example, one embodiment of the invention uses low-cost coulomb counting circuit components that reduce the invention's complexity.

From the above description of the invention it is manifest that various techniques can be used for implementing the concepts of the present invention without departing from its scope. Moreover, while the invention has been described with specific reference to certain embodiments, a person of ordinary skill in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many rearrangements, modifications, and substitutions without departing from the scope of the invention.

1. A system for accurately estimating a run time of a battery utilized by an electronic device, the system comprising:
a voltage capture circuit, said voltage capture circuit configured to measure a voltage of said battery during a sleep mode;
a coulomb counting circuit, said coulomb counting circuit configured to measure a charge of said battery.

2. The system of claim 1, wherein said voltage capture circuit is further configured to measure an open-circuit voltage of said battery.

3. The system of claim 2, wherein said voltage capture circuit is further configured to store said open-circuit voltage for utilization after said sleep mode.

4. The system of claim 1, wherein said voltage capture circuit comprises a sample-and-hold circuit.

5. The system of claim 1, wherein said voltage capture circuit comprises an analog-to-digital converter.

6. The system of claim 1, wherein said voltage capture circuit is configured to provide a voltage capture circuit output to a microprocessor of said electronic device.

7. The system of claim 1, wherein said coulomb counting circuit comprises an analog-to-digital converter.

8. The system of claim 7, wherein said analog-to-digital converter comprises a sigma-delta converter.

9. The system of claim 1, wherein said coulomb counting circuit comprises a comb filter.

10. The system of claim 1, wherein said coulomb counting circuit comprises a digital accumulator.

11. The system of claim 1, wherein said coulomb counting circuit is configured to provide a coulomb counting circuit output to a microprocessor of said electronic device.

12. The system of claim 1, further comprising a current sensor configured to provide a current signal to said coulomb counting circuit.

13. The system of claim 12, further comprising a low-pass filter configured to filter said current signal.

14. A system for accurately estimating a run time of a battery utilized by an electronic device, the system comprising:
a voltage capture circuit, said voltage capture circuit configured to measure a an open circuit voltage of said battery during a sleep mode;
a coulomb counting circuit, said coulomb counting circuit configured to measure a charge of said battery during said sleep mode.

15. The system of claim 14, wherein said voltage capture circuit is further configured to store said open-circuit voltage for utilization after said sleep mode.

16. The system of claim 14, wherein said voltage capture circuit comprises a sample-and-hold circuit.

17. The system of claim 14, wherein said voltage capture circuit comprises an analog-to-digital converter.

18. The system of claim 14, wherein said coulomb counting circuit comprises a sigma-delta converter.

19. The system of claim 14, wherein said coulomb counting circuit comprises a comb filter.

20. The system of claim 14, wherein said coulomb counting circuit comprises a digital accumulator.
